(19) United States
(12) Patent Application Publication
(10) Pub. No.: US 2006/0166036 A1
(43) Pub. Date: Jul. 27, 2006

(54) Organic light-emitting diodes and displays incorporating the same

(75) Inventor: Chung-Chun Lee, Lunbei Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/117,007

(22) Filed: Apr. 28, 2005

(30) Foreign Application Priority Data
Jan. 20, 2005 (TW) 94101649

(51) Int. Cl. H01L 51/54; H05B 33/14

(52) U.S. Cl. 428/690; 428/917; 313/504; 313/506; 257/102; 257/103; 257/E51.049; 257/E51.043; 257/E51.05

(57) ABSTRACT

An organic light-emitting diode. The organic light-emitting diode includes a cathode, an anode, and an emitting layer disposed between the cathode and the anode, wherein the emitting layer comprises a bipolar compound and an assistant dopant. The invention also provides a display comprising the organic light-emitting diode.

### BACKGROUND

The present invention relates to an organic electroluminescent device, and more specifically to an organic light-emitting diode and a display comprising the same.

Organic electroluminescent devices are popular in flat panel display industry due to their high illumination, light weight, self-illumination, low power consumption, simple fabrication, rapid response time, wide viewing angle, and no backlight requirement.

When an external electric field is applied to an organic electroluminescent device, electrons and holes are injected respectively into organic electroluminescent layer and then recombined to form excitons. Energy is further transferred from excitons to luminescent molecules with continuously application of an electric field. Finally, luminescent molecules emit light converted from energy. A common organic electroluminescent device structure comprises an anode, a hole-transportinging layer, an emitting layer, a hole-blocking layer, an electron-transportinging layer, and a cathode. A complex organic electroluminescent device, however, may further comprise a hole-injection layer disposed between an anode and a hole-transportinging layer or an electron-injection layer disposed between a cathode and an electron-transportinging layer to improve injection efficiency of carriers, reducing driving voltage or increasing recombination thereof.

Alq₃ is a common host of a conventional emitting layer. Alq₃ complex, however, may be easily ionized to form an Alq₃⁺, when considerable quantities of holes exist. Alq₃⁺is an extremely unstable substance and deteriorates the lifespan of devices.

H. Aziz provides a method of inhibiting Alq₃⁺formation adding a great quantity of hole-blocking substance to a hole-transporting layer to reduce combination of holes and Alq₃ complex. H. Aziz also teaches adding hole-transporting substance to an emitting layer to increase recombination of holes and electrons through hole-transporting substance and electron-transporting substance to inhibit Alq₃⁺formation. T.K. Hatwar teaches adding a smaller quantity (about 0.1˜25%) of hole-trapping substance to an emitting layer, hole-transporting layer, or electron-transporting layer to inhibit Alq₃⁺formation. The above methods cannot thoroughly solve the problem of Alq₃⁺formation, because Alq₃ is still a host of an emitting layer.

### SUMMARY

The invention provides an organic light-emitting diode comprising a cathode, an anode, and an emitting layer disposed between the cathode and the anode, wherein the emitting layer comprises a bipolar compound and an assistant dopant.

The invention also provides a display comprising the above organic light-emitting diode, and a driving circuit coupled to the organic light-emitting diode to drive the organic light-emitting diode.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a cross section of an organic light-emitting diode of the invention.

FIG. 2 is a top view of a display of the invention.

FIG. 3 shows lifetime curves of organic light-emitting diodes of the invention.

### DETAILED DESCRIPTION

The invention provides an organic light-emitting diode comprising a cathode, an anode, and an emitting layer disposed between the cathode and the anode, wherein the emitting layer comprises a bipolar compound and an assistant dopant.

The cathode or anode should be a transparent electrode, that is, the cathode and the anode may have the same or different materials, and they may comprise a single layer or multiple layers comprising metal, transparent oxide, or combinations thereof. The metal may be Al, Ca, Ag, Ni, Cr, Ti, Mg, or Mg-Ag alloy. The transparent oxide comprises ITO, AZO, ZnO, InN, or SnO₂.

The emitting layer has a thickness of about 50˜2000 Å. The bipolar compound and the assistant dopant have a volume ratio of about 90:10˜51:49, preferably, 80:20.

The invention provides a new emitting layer comprising a bipolar compound having electron/hole mobility exceeding 10⁻⁷ cm²v⁻¹s⁻¹, preferably, 10⁻⁵ cm²v⁻¹s⁻¹ and less dopant to greatly improve electrical performance and lifetime of the organic light-emitting diode.

The bipolar compound may be anthracene derivative, fluorene derivative, spirofluorene derivative, pyrene derivative, oligomer, or combinations thereof. The anthracene derivative may comprise 9,10-di-(2-naphthyl)anthracene (AND), 2-(t-butyl)-9,10-di(2-naphthyl)anthracene (TBADN), or 2-methyl-9,10-di(2-naphthyl)anthracene (MADN). The fluorene derivative may comprise Ter(9,9-diphenylfluorene) or Ter(9,9-dinaphthylfluorene). The spirofluorene derivative may be 2,7-bis[2-(4-tert-butylphenyl)pyrimidine-5-yl]-9,9′-spirobifluorene. The pyrene derivative may be 1,3,6,8-tetraphenylpyrene, 1,3,6,8-tetra(o-methylphenyl)pyrene, or 1,3,6,8-tetra(2-naphthyl)pyrene. The bipolar compounds provided by the invention are not limited to the foregoing compounds. All of the bipolar compounds having an electron/hole mobility exceeding 10⁻⁷ cm²v⁻¹s⁻¹ are suitable for use in the invention.

The assistant dopant may be an organometallic complex, such as Aluminum(III)tris(8-hydroxyquinoline) (Alq₃), Aluminum(III)bis(2-methyl-8-quinolinato)phenolates (BAlq₃), Gallium(III)tris(8-hydroxyquinoline) (Gaq₃), or Indium(III)tris(8-hydroxyquinoline) (Inq₃). The invention also provides an emitting material having a concentration of about 0.1˜25%, such as 10-(1,3-benzothiazol-2-yl)-1, 1,7,7-tetramethyl-2,3,6,7-tetra-hydro-1H,5H,11H-pyrano[2, 3-f]pyrido[3,2,1-ij]quinolin-11-one (C-545T) or 4-(Dicyanomethylene)-2-t-butyl-6-(1,1,7,7-tetramethyljulolidyl-9-enyl)-4H-pyran (DCJTB).

A bipolar compound is a host of an emitting layer of the invention. An energy barrier between a cathode/anode and an emitting layer can be reduced by adding a bipolar compound and an assistant dopant, increasing electron-transporting efficiency. Additionally, less Alq₃⁺is formed due to much lower concentration of Alq₃ complex, effectively prolonging lifetime of a device. For example, the L₅₀ of an organic light-emitting diode is above 2000 hours with an initial luminance of 2000cd/m² of the invention.

An organic light-emitting diode further comprises a hole-injection layer or a hole-transporting layer disposed between an anode and an emitting layer and an electron-transporting layer or an electron-injection layer disposed between a cathode and an emitting layer. The hole-injection layer comprises a polymer containing F, C, and H, porphyrin derivative, or p-doped diamine derivative. The porphyrin derivative may comprise metallophthalocyanine derivative, such as copper phthalocyanine.

The hole-transporting layer comprises diamine derivative, such as N,N′-bis(1-naphyl)-N,N′-diphenyl-1, 1′-biphenyl-4,4′-diamine (NPB), N,N′-diphenyl-N, N′-bis(3-methylphenyl)-(1,1′-biphenyl)-4,4′-diamine (TPD), or 2T-NATA. The hole-transportinging layer has a thickness of about 50˜5000 Å.

The electron-transporting layer comprises Aluminum(III)tris(8-hydroxyquinoline) (Alq₃), Aluminum(III)bis(2-methyl-8-quinolinato)phenolates (BAlq₃), Gallium(III)tris(8-hydroxyquinoline) (Gaq₃), or Indium(III)tris(8-hydroxyquinoline) (Inq3). The electron-transporting layer has a thickness of about 50˜5000 Å.

The electron-injection layer may comprise alkali halide, alkaline halide, alkali oxide, or metal carbonate, such as LiF, CsF, NaF, CaF₂, Li₂O, Cs₂O, Na₂O, Li₂CO₃, Cs₂CO₃, Na₂CO₃, CsNO₃, LiNO₃, or NaNO₃. The electron-injection layer has a thickness of about 5˜1500 Å.

The invention also provides a display comprising the disclosed organic light-emitting diode and a driving circuit coupled to the organic light-emitting diode to drive the organic light-emitting diode. The driving circuit comprises at least one thin film transistor.

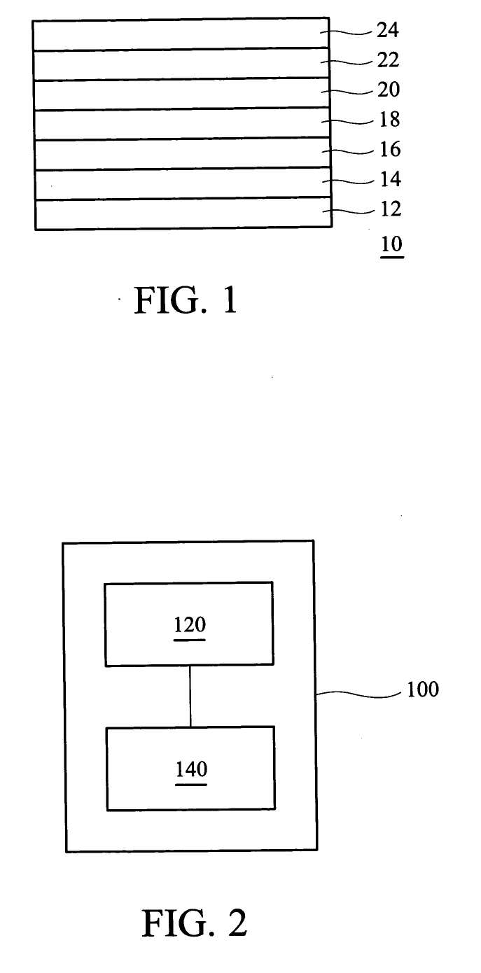

Referring to FIG. 1, an organic light-emitting diode provided by the invention is disclosed. The organic light-emitting diode 10 comprises an anode 12, a hole-injection layer 14, a hole-transporting layer 16, an emitting layer 18, an electron-transporting layer 20, an electron-injection layer 22, and a cathode 24, wherein the emitting layer 18 comprises a bipolar compound and a dopant.

Referring to FIG. 1, a method of fabricating an organic light-emitting diode is provided. First, an anode 12 is provided. Next, a hole-injection layer 14, a hole-transporting layer 16, an emitting layer 18, an electron-transporting layer 20, an electron-injection layer 22, and a cathode 24 are evaporated on the anode 12 in order. Finally, the diode is packaged to form an organic light-emitting device.

Referring to FIG. 2, a display provided by the invention is disclosed. The display 100 comprises an organic light-emitting diode 120 and a driving circuit 140 coupled to the organic light-emitting diode 120 to drive the organic light-emitting diode 120.

### EXAMPLES

### Comparative Example 1

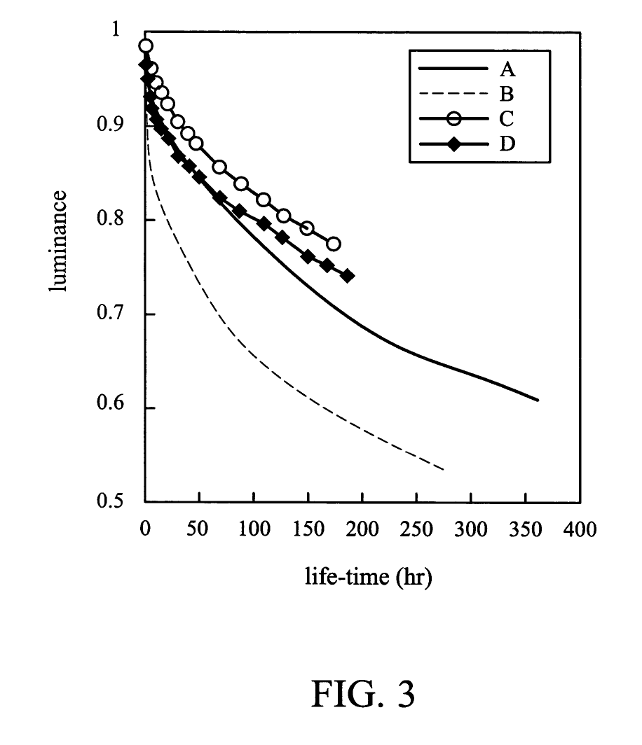

Referring to FIG. 1, a method of fabricating an organic light-emitting diode (device A) is disclosed in the following. First, an ITO anode 12 was provided on a substrate. The anode 12 was then treated with UV ozone. Next, copper phthalocyanine was evaporated on the ITO anode 12 to form a hole-injection layer 14. Next, NPB was evaporated on the hole-injection layer 14 to form a hole-transporting layer 16. Alq₃ and C-545T were then co-evaporated on the hole-transporting layer 16 to form an emitting layer 18. The volume ratio of Alq₃ and C-545T was 100:1. Next, Alq₃ was evaporated on the emitting layer 18 to form an electron-transporting layer 20. Next, LiF was evaporated on the electron-transporting layer 20 to form an electron-injection layer 22. Finally, Al was evaporated on the electron-injection layer 22 to form a cathode 24. The lifetime curve A of the device A is shown in FIG. 3.

### Comparative Example 2

Referring to FIG. 1, another method of fabricating an organic light-emitting diode (device B) is disclosed in the following. First, an ITO anode 12 was provided on a substrate. The anode 12 was then treated with UV ozone. Next, copper phthalocyanine was evaporated on the ITO anode 12 to form a hole-injection layer 14. Next, NPB was evaporated on the hole-injection layer 14 to form a hole-transporting layer 16. Alq₃, MADN, and C-545T were then co-evaporated on the hole-transporting layer 16 to form an emitting layer 18. The volume ratio of Alq₃, MADN, and C-545T was 90:10:1. Next, Alq₃ was evaporated on the emitting layer 18 to form an electron-transporting layer 20. Next, LiF was evaporated on the electron-transporting layer 20 to form an electron-injection layer 22. Finally, Al was evaporated on the electron-injection layer 22 to form a cathode 24. The lifetime curve B of the device B is shown in FIG. 3.

### Example 1

Referring to FIG. 1, a method of fabricating an organic light-emitting diode (device C) of the invention is provided. First, an ITO anode 12 was provided on a substrate. The anode 12 was then treated with UV ozone. Next, copper phthalocyanine was evaporated on the ITO anode 12 to form a hole-injection layer 14. Next, NPB was evaporated on the hole-injection layer 14 to form a hole-transporting layer 16. MADN, Alq₃, and C-545T were then co-evaporated on the hole-transporting layer 16 to form an emitting layer 18. The volume ratio of MADN, Alq₃, and C-545T was 80:20:1. Next, Alq₃ was evaporated on the emitting layer 18 to form an electron-transporting layer 20. Next, LiF was evaporated on the electron-transporting layer 20 to form an electron-injection layer 22. Finally, Al was evaporated on the electron-injection layer 22 to form a cathode 24. The lifetime curve C of the device C is shown in FIG. 3.

### Example 2

Referring to FIG. 1, another method of fabricating an organic light-emitting diode (device D) of the invention is provided. First, an ITO anode 12 was provided on a substrate. The anode 12 was then treated with UV ozone. Next, copper phthalocyanine was evaporated on the ITO anode 12 to form a hole-injection layer 14. Next, NPB was evaporated on the hole-injection layer 14 to form a hole-transporting layer 16. MADN, Alq₃, and C-545T were then co-evaporated on the hole-transporting layer 16 to form an emitting layer 18. The volume ratio of MADN, Alq₃, and C-545T was 60:40:1. Next, Alq₃ was evaporated on the emitting layer 18 to form an electron-transporting layer 20. Next, LiF was evaporated on the electron-transporting layer 20 to form an electron-injection layer 22. Finally, Al was evaporated on the electron-injection layer 22 to form a cathode 24. The lifetime curve D of the device D is shown in FIG. 3.

Referring to FIG. 3, the devices C and D using MADN as a host of an emitting layer (volume percentage thereof exceeds 50%) provided by the invention show longer lifetime than the related devices A and B using MADN as a dopant of an emitting layer (volume percentage thereof lower than 50%).

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic light-emitting diode, comprising:
a cathode and an anode; and
an emitting layer disposed between the cathode and the anode, wherein the emitting layer comprises a bipolar compound and an assistant dopant.

2. The organic light-emitting diode as claimed in claim 1, wherein the cathode is a transparent electrode.

3. The organic light-emitting diode as claimed in claim 1, wherein the anode is a transparent electrode.

4. The organic light-emitting diode as claimed in claim 1, wherein the cathode comprises metal, transparent oxide, or combinations thereof.

5. The organic light-emitting diode as claimed in claim 1, wherein the anode comprises metal, transparent oxide, or combinations thereof.

6. The organic light-emitting diode as claimed in claim 1, wherein the cathode and the anode are the same material.

7. The organic light-emitting diode as claimed in claim 1, wherein the emitting layer has a thickness of about 50 Å to 2000 Å.

8. The organic light-emitting diode as claimed in claim 1, wherein the bipolar compound and the assistant dopant have a volume ratio of about 90:10 to 51:49.

9. The organic light-emitting diode as claimed in claim 1, wherein the bipolar compound has an electron/hole mobility exceeding 10⁻⁷ cm²v⁻¹s⁻¹.

10. The organic light-emitting diode as claimed in claim 1, wherein the bipolar compound comprises an anthracene derivative.

11. The organic light-emitting diode as claimed in claim 10, wherein the anthracene derivative comprises 9,10-di-(2-naphthyl)anthracene (AND), 2-(t-butyl)-9,10-di(2-naphthyl)anthracene (TBADN), or 2-methyl-9,10-di(2-naphthyl)anthracene (MADN).

12. The organic light-emitting diode as claimed in claim 1, wherein the assistant dopant comprises an organometallic complex.

13. The organic light-emitting diode as claimed in claim 12, wherein the organometallic complex comprises Aluminum(III)tris(8-hydroxyquinoline) (Alq₃), Aluminum(III)bis(2-methyl-8-quinolinato)phenolates (BAlq₃), Gallium(III) tris(8-hydroxyquinoline) (Gaq₃), or Indium(III)tris(8-hydroxyquinoline) (Inq₃).

14. The organic light-emitting diode as claimed in claim 1, wherein the emitting layer comprises an emitting material having a concentration of about 0.1 to 25%.

15. The organic light-emitting diode as claimed in claim 14, wherein the emitting material comprises 10-(1, 3-benzothiazol-2-yl)-1,1,7,7-tetramethyl-2,3,6, 7-tetra-hydro-1H,5H,11H-pyrano[2,3-f]pyrido[3,2, 1-ij]quinolin-11-one (C-545T) or 4-(Dicyanomethylene)-2-t-butyl-6-(1, 1,7,7-tetramethyljulolidyl-9-enyl)-4H-pyran (DCJTB).

16. The organic light-emitting diode as claimed in claim 1, further comprising an electron-injection layer disposed between the cathode and the emitting layer.

17. The organic light-emitting diode as claimed in claim 1, further comprising an electron-transporting layer disposed between the cathode and the emitting layer.

18. The organic light-emitting diode as claimed in claim 1, further comprising a hole-injection layer disposed between the anode and the emitting layer.

19. The organic light-emitting diode as claimed in claim 1, further comprising a hole-transporting layer disposed between the anode and the emitting layer.

20. A display, comprising:
an organic light-emitting diode of claim 1; and
a driving circuit coupled to the organic light-emitting diode, driving the organic light-emitting diode.

21. The display as claimed in claim 20, wherein the driving circuit comprises at least one thin film transistor.
